(19) United States
(12) Patent Application Publication
(10) Pub. No.: US 2009/0020615 A1
(43) Pub. Date: Jan. 22, 2009

(54) METHOD OF MAKING SMART CARDS WITH AN EXCAPSULANT

(76) Inventor: Gordhanbhai N. Patel, Somerset, NJ (US)

Correspondence Address: NEXSEN PRUET, LLC, P.O. BOX 10648, GREENVILLE, SC, 29603, US

(21) Appl. No.: 12/279,004

(22) PCT Filed: Oct. 9, 2006
(86) PCT No.: PCT/US06/39623

§ 371 Date: Aug. 11, 2008

Related U.S. Application Data
(60) Provisional application No. 60/775,241, filed on Feb. 21, 2006.

(51) Int. Cl. G06K 19/077; H01L 21/02

(52) U.S. Cl. 235/492; 438/127; 257/E21.002

(57) ABSTRACT

A method of making smart cards with an encapsulant (23) without having a bulge by heat lamination is disclosed. The core material (21) is cut for the encapsulant (23), such as a sensor or electronic component and laminated with a bottom layer (24) to create a cavity (22). The encapsulant (23) is introduced in the cavity (22) and laminated with another layer (27).

### BACKGROUND OF THE INVENTION

This invention relates to a method for making smart cards having a cavity for an encapsulant without a bulge.

Smart cards are typically one composite piece of a plastic. It is almost impossible to access the encapsulated electronic components of smart cards without cutting the cards. Smarts cards are typically tamper resistant and tamper evident.

Smart cards are used as bankcards, ID cards, telephone cards and the like. Smart cards are usually made by embedding electronic components between several layers of plastic sheets in a sandwich array. If the electronic components can withstand high temperature, smart cards are made by encapsulating them in molten polymeric materials. Recently smarts cards are made by encapsulating electronic components in polymeric materials by a technique commonly known as reaction injection molding.

U.S. Pat. No. 6,902,116 describes a method of making smart cards having a card core with two or more laminated layers. The cavity is milled into one or more of the layers to receive the electronic circuitry. The cavity is then filled. The core layers are then laminated together, along with protective overlays. Alternative fabrication methods include co-extrusion and injection molding.

U.S. Pat. Nos. 6,886,246 and 6,404,643 to Chung describe a method for making an article having an electronic device embedded therein comprising a substrate having first and second opposing broad planar surfaces; mounting an electronic device on the first broad planar surface of the substrate; and applying a layer of melt-flowable adhesive of substantially uniform thickness on the first broad planar surface of the substrate to cover the electronic device. The article produced thereby has the electronic device encapsulated by the layer of melt-flowable adhesive.

U.S. Pat. Nos. 6,241,153 and 6,256,873 describe methods of making smart cards having high quality external surfaces by making use of a primer/adhesive (and, optionally, anchor hooks) on the lower surface of an electrical component in order to affix said electrical component to a thermosetting material that becomes the core layer of said cards.

European patent 350179 discloses a smart card wherein electronic circuitry is encapsulated in a layer of a reaction moldable polymeric material that is introduced between the card's two surface layers. Similarly European Patent Application 95400365.3 teaches a method for making contactless smart cards where an electronic module is encapsulated with a polymerizable resin material between upper and lower thermoplastic sheets.

U.S. Pat. No. 5,399,847 teaches a credit card that is comprised of three layers, namely, a first outer layer, a second outer layer and an intermediate layer. The intermediate layer is formed by injecting a thermoplastic binding material that encases the electronic elements in the intermediate layer material. The binding material is made of a blend of copolyamides or a glue having two or more chemically reactive components that harden upon contact with air. The outer layers of this smart card can be made up of various polymeric materials such as polyvinyl chloride or polyurethane.

U.S. Pat. No. 5,417,905 teaches a method for manufacturing plastic credit cards wherein a mold tool comprised of two shells is closed to define a cavity for producing such cards. A label or image support is placed in each mold shell.

Methods of making smart cards is also disclosed in other patents including U.S. Pat. Nos. 4,339,407, 4,961,893, 5,350,553, 5,423,705, 5,498,388 and 5,510,074. All of these prior art methods for making smart cards are usually for encapsulating electronic components or circuitry inside the smart card. Often the electronic components are held in place with a glue sometimes isotropic thermoset adhesive materials.

Patent application number WO 2004/077097 describes a radiation sensitive dosimeter. The radiation sensitive dosimeter is typically made by sandwiching a radiation sensitive coating or strip between two plastic layers with a pressure sensitive adhesive.

Radiation sensitive materials, such as diacetylenes (R—C≡C—C≡C—R, where R is a monovalent group) and processes that can be used for making radiation sensitive coatings or strips for making Self-indicating Instant Radiation Alert Dosimeter (referred herein as SIRAD) are listed in patent application number WO 2004/077097 and WO 2004/017095 and references cited therein. The encapsulant for making SIRAD cards, a piece of plastic films or plaque of radiation sensitive materials is described in Patent application number WO 2004/077097. The encapsulant for SIRAD is also referred herein to as “radiation sensitive coating”, “radiation sensitive strip” or “SIRAD strip”. An encapsulant in general is also referred to as sensor, including radiation sensor.

U.S. patent application No. WO 2004/077097 and WO 2004/017095 describe a method of making temper resistant SIRAD cards by reaction injection molding. This application also mentions that the cards can be made by heat lamination method.

### SUMMARY OF THE INVENTION

Provided is a method and its variations of making smart cards by encapsulating an encapsulant in a core material having a cavity essentially the same shape as that of an encapsulant. The core material would have the same or close to the same thickness as that of an encapsulant. The core material is then cut having essentially the same shape or close to that of the encapsulant to create a hole. The hole in the core material is also referred to herein as a cavity or well. The core material is then laminated with a bottom support layer, preferably by heat lamination method. The encapsulant is then inserted in the cavity and laminated with a top layer, preferably by heat lamination, to seal the encapsulant to make the card. The encapsulant could be any material, such as an electronic device or component, a circuitry, a sensor and alike and referred them herein as to encapsulant, element or sensor.

Provided are processes of selecting (1) a core material having the thickness essentially the same as that of the encapsulant and able to bond acceptably strong with top and bottom layers with an adhesive; (2) bottom and top layers having desired thicknesses, transparencies or opaqueness, and ability to bond with the core material with an adhesive, and (3) an adhesive to bond the bottom and top layers with the core material. Provided are steps of (1) cutting the core material with essentially the same shape as that of the encapsulant and (2) laminating with a bottom layer with an adhesive to create a cavity or well for the encapsulant.

Provided are different methods of creating a cavity in the core material by processes such as die-cutting and laser-cutting.

Provided is a process of picking up the encapsulant and placing in the cavity.

Provided is a process of applying the top layer over the core layer and encapsulant and laminating with an adhesive.

Provide is a method of production cards on line on a continuous basis

Provided is a method of making SIRAD type cards.

Provided also is a method of making cavity by commonly known as mold process where the core material is molded with the cavity.

Provided is a process of molding core layer with cavity and the bottom layer as one piece.

Provided is a process of molding core layer with cavity and the bottom layer as one piece and further printed with required information on the bottom and color reference bars on the top.

A particularly preferred embodiment is provided in a multi-layer smart card with a top layer, a core layer having at least one cavity, an encapsulant in the cavity, a bottom layer and adhesive layers between the top layer and the core layer and between the core layer and the bottom layer.

Another embodiment is provided in a process of making a smart card. The process includes providing a core layer with a cavity; providing a bottom layer; laminating the bottom layer to the core layer; inserting an encapsulant is the cavity; and laminating a top layer to the core layer.

Yet another embodiment is provided in a process of making a smart card. The process includes providing a first layer; providing a second layer wherein the second layer has at least one cavity; providing a third layer; inserting an encapsulant into the cavity; placing the first layer, the second layer and the third layer in layered relationship; and fusing the layered relationship to form the smart card.

### BRIEF DESCRIPTION OF THE DRAWINGS

FIG. 1 is a cross sectional view of different layers and a method used for making SIRAD cards.

FIG. 2 is an exploded side view of SIRAD card illustrating the components and manufacture.

FIG. 3 is a cross sectional view of a card with more than one bottom layers.

FIG. 4 is a schematic presentation of the manufacturing steps for a SIRAD cards.

FIG. 5 is a schematic presentation of a sheet of core layers and sensing strips for manufacturing dual-sensor SIRAD cards.

FIG. 6 is a schematic presentation of four layers for making dual-sensor SIRAD cards with printing of each layer.

FIG. 7 is a schematic presentation of a preferred process for making dual-sensor SIRAD cards from four layers.

FIG. 8 is a schematic presentation of five layer cards and methods for making dual-sensor SIRAD cards with printing on some layers.

FIG. 9 is a schematic presentation of six layers for making dual-sensor SIRAD cards with printing on some layers.

FIG. 10 is a example of printing on a black protective cover of SIRAD card.

FIG. 11 is an example of printing on a core layer for a dual-sensor SIRAD card.

FIG. 12 is an example of printing on the back of the bottom layer for a SIRAD card.

### DETAILED DESCRIPTION OF PREFERRED EMBODIMENTS

Provided herein is a method for making smart cards and the cards manufactured thereby. In order to explain the invention, a radiation sensing strip is used as a encapsulant in the following drawings and Teslin® is used as the core material.

The invention can be best described by reference to the Figures. The smart card is also referred to as a device. In the disclosure below the encapsulant is a radiation sensing strip described in Patent Applications Nos. WO 2004/077097 and WO 2004/017095 both of which are incorporated by reference, but it could be any other sensor, electronic device or for that matter, any other encapsulant. Similarly, the process is exemplified with making of SIRAD cards but any other type of smart cards can be made using the procedures disclosed below.

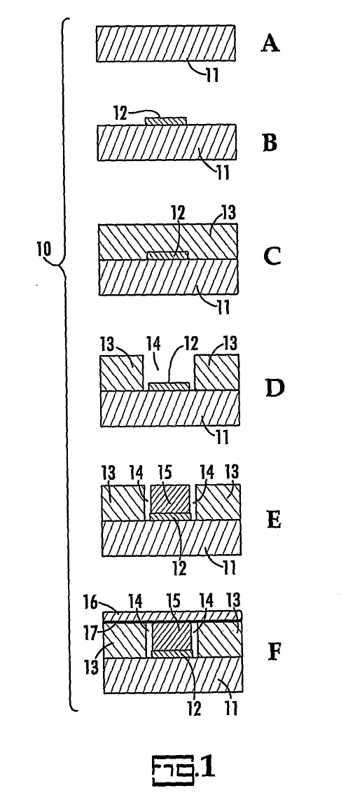

A sequence for manufacturing smart cards for monitoring radiation, typically referred to as SIRAD, is illustrated schematically in FIG. 1 generally at 10. A pre-printed bottom opaque layer, 11, such as a mineral filled PVC is the initial layer as provided at step A. The pre-printed bottom opaque layer is overlayed with a non-stick release film, 12, at step B. The non-stick layer, 12, also referred to as a release layer, is required to peel off of the die-cut area for the sensor. A core layer, 13, such as PVC or polyolefins such as Teslin®, a microporous battery membrane supplied by PPG Industries, Pittsburgh, Pa., is applied by a conventional high temperature, high pressure lamination method of making credit cards which overlays the non-stick layer, 12 and opaque layer, 11, at step C. The core layer is then die-cut and peeled off with a sharp object such as a knife to create a cavity, 14, for the sensing strip, 15, at step D and the sensing strip is inserted into the cavity at step E. A clear polyester film, 16, having a PSA layer, 17 is laminated over the core layer at step F. This process for forming a SIRAD card is functional yet the top film with PSA can be peeled off. The process is tedious, labor intensive, expensive and difficult to perfect. There is a need for a simpler, less expensive and less tedious method. An improved method is provided herein.

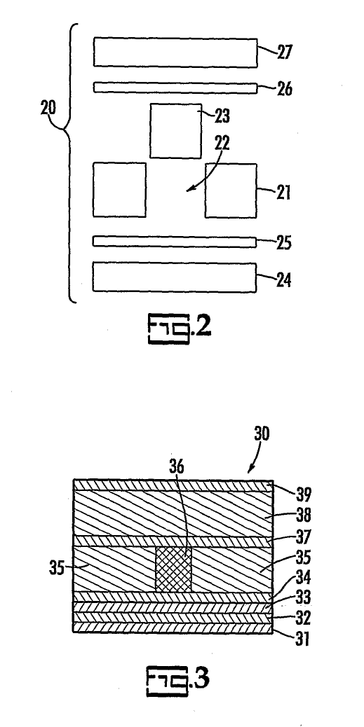

A preferred method for manufacturing a smart card will be described with reference to FIG. 2 wherein the smart card is shown in exploded view generally at 20. In FIG. 2, the core layer, 21, preferably has a pre-cut cavity, 22, which has approximately the same dimensions as that of the encapsulant, 23. The cavity of the core material is preferably die-cut, however, it can also be made by any other known method such as with a laser cutting, pre-molding or casting the core layer with the cavity. The core layer is then bonded to a bottom layer, 24, preferably by an adhesive layer, 25, such as a pressure sensitive adhesive (PSA) or a heat activated adhesive (HAA). The encapsulant, 23, is then inserted into the cavity, 22, and laminated with a top layer, 27, by an adhesive layer, 26, such as a PSA or HAA. The card can then be die-cut to any desired shape, preferably that of a credit card.

The smart cards can have more than one bottom, core and top layers as shown in FIG. 3. In FIG. 3 the card is generally represented at 30. The card comprises a printable layer, 31. Supra the printing layer is a bottom opaque layer, 33, with adhesive layers, 32 and 34, on either side thereof. The adhesive layers bond the bottom opaque layer to the printed layer on one side and a sensor layer on the other wherein the sensor layer comprises a core layer, 35, comprising a cavity wherein the sensor, 36, is received in the cavity. It is most preferable that the cavity and sensor are approximately the same dimensions. A transparent top layer, 38, is laminated to the sensor layer preferably by an adhesive layer, 37, such as an HAA or PSA layer. An optional layer, 39, may be provided if desired. The optional layer may comprise a scratch off bar which may be printed or it may comprise a protective layer such as a black PET. The printable layer is preferably a TCA (trichloro acetic acid) etched polyethylene terephthalate (PET) film with a thickness of about 5 to 7 mil and printing on the exterior side. The adhesive layers are preferably either PSA or HAA layers with HAA being preferred. The adhesive layers are preferably about 2 to 4 mils thick for most adhesives. It is desired that the adhesive layers be as thin as possible without compromise in adhesion. Certain adhesives may allow the layer thickness to be lower. The core layer is preferably a Teslin® or Artisyn® layer. Teslin® is a dimensionally stable, highly filled, single layer, microporous film. It is polyolefin-based with 60% of its weight comprised of non-abrasive filler and 65% of its volume comprised of air. Teslin® is available in various gauges from PPG Industries, Inc. Teslin® and Atrisyn® are the most preferred for demonstration of the present invention. Artisyn® is a uncoated, single layer, highly filled polyolefin which contains approximately 50% non-abrasive filler by weight and about 60% air. Artisyn® is available at Protect-All Print Media, Inc. The core layer is preferably about 7 to 14 mils thick. The core layer can be printed if desired to provide color or information. The transparent top layer is preferably a PET film with a thickness of about 5-7 mils. If an optional cover sheet is desired a 2-sided adhesive film wherein the adhesive is either a PSA or an IAA can be applied to the transparent layer with a black PET film laminated thereon.

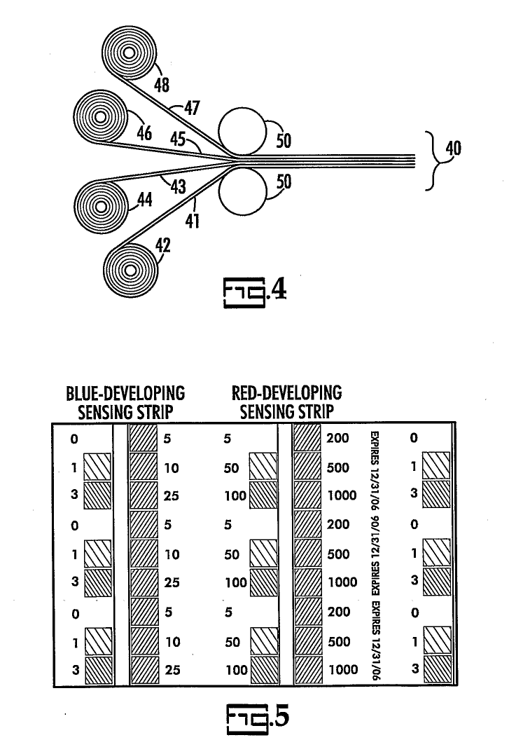

The cards can be manufactured on line in a continuous way as exemplified in FIG. 4. In FIG. 4 rolls of different layers such as top and bottom layers with an adhesive and core layer with sensing strip. In FIG. 4, a series of films are provided on rolls and moved through a pair of nip rollers to form a laminated layered structure. In one embodiment, a bottom layer, 41, fed from a first roller, 42, comprises PET with an adhesive layer, preferably HAA, on one surface. The bottom layer is fed with the adhesive layer interior to the PET film. A sensing layer, 43, fed from a second roller, 44, provides an alternating pattern of sensing strip and core material. The sensing strip is preferably integral to the core material and encased in a cavity therein such that the thickness of the layer is constant. Supra to the sensing layer is a top layer comprising a PET support with an adhesive layer, preferably HAA, coated thereon. The adhesive is between the PET and sensing layer. A protective layer, 45, fed from roller, 46, preferably comprises a PET with a hot melt adhesive. Supra the top layer is an optional, but preferred, pre-printed black protective film, 47, with a thin band of PSA tape thereon thereby allowing the protective film to be removed after use. The black protective film, 47, is fed by roller 48. The layers are brought into layered arrangement and laminated into a single layered structure by a pair of nip rollers, 50, which are preferably heated thereby resulting in the layered structure, 40, which is preferably cut into the desired size.

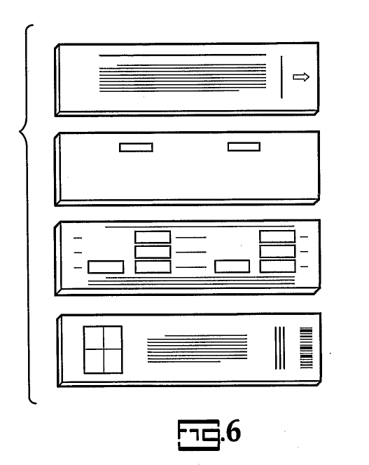

A finished sensing layer is illustrated in FIG. 5. In FIG. 5, the core layer has pre-printed scales, instructions, etc. Embedded therein are sensing strips. In the embodiment illustrated a blue sensing strip and red sensing strip are provided.

Schematic presentations of different ways dual-sensor SIRAD cards can be made are shown in FIGS. 6-9.

In FIG. 6, the bottom layer is a 6-8 mil opaque PET film with writable bottom surface printed with instructions and about a 2 mil thick layer of HAA on the top. The sensing layer is a 10-14 mil white or opaque film comprising Teslin®, Artisyn® or PET with color reference bars printed thereon. Other information is printed on the top surface. If PET is used it is preferable to have an HAA layer on each side. The top layer comprises a 6-8 mil transparent PET film with scratch-off opaque or black bars printed on a top antiglare or satin surface. About 2 mil thick layer of HAA is on the bottom. The protective layer is a 4 mil thick black protective PET film with instructions printed on the top and a 2-3 mil thick and 3-4 mm wide HAA or PSA tape.

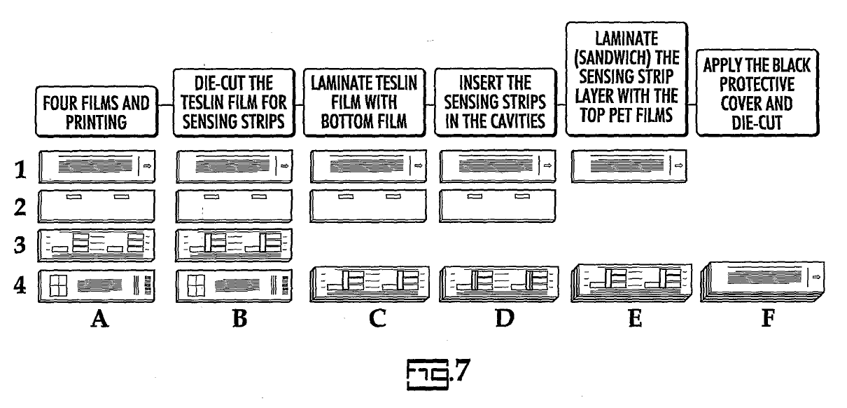

FIG. 7 illustrates schematically the process of the present invention. At step A, four discrete films, 1-4, are provided. Film 1 is a top layer, film 2 is a PET layer, film 3 is a core layer and film 4 is a bottom layer. The core layer, preferably a Teslin® (D layer, is die-cut to form a cavity the size of the sensing strip at Step B. The bottom layer and core layer are laminated at step C. The sensing strip is inserted into the cavities formed in step B at step D. Layer 2 is laminated to the composite layer from step C at step E with the sensor there between in the cavity. The top layer is laminated to the composite from step E and step F. As indicated in FIG. 7 each layer may have printings incorporated thereon.

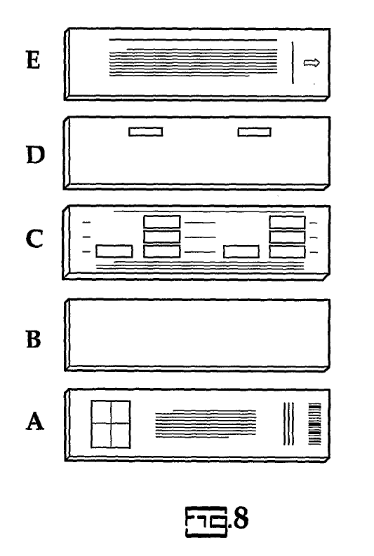

FIG. 8 illustrates a five layer structure that may be formed into a composite in a manner analogous to the described relative to FIG. 7. In FIG. 8, the bottom layer, A, comprises an opaque TCA-PET layer with a thickness of about 2-5 mil. The bottom surface is preferably printed with instructions preferably in black. A second bottom layer, B, preferably comprises a 2-5 mil thick PET film having an adhesive coated at about 1-2 mil thickness on each side. The adhesive is preferably HAA or PSA. Layer C is the sensing layer comprising a 10-14 mil thick white opaque layer preferably selected from Teslin® ®, Artysin® or TCA-PET with color reference bars and other printed information printed thereon. The layer has a cavity with a sensor in the cavity. Layer D is preferably a 3-10 mil thick transparent layer which is preferably PET. Scratch-off opaque-black bars are printed on the top. The surface is preferably an antiglare, or satin, surface. The layer has an adhesive layer on the bottom which is preferably about 2 mil thick. The adhesive is preferably HAA or PSA. Layer E is a top layer which is preferably a 4 mil thick black PET film with instructions printed on the top. The layer has a 2-3 mil thick and 3-4 mm wide adhesive preferably selected from HAA and PSA.

FIG. 9 illustrates a six layer construction which would be prepared in a manner analogous to that described relative to FIG. 7. In FIG. 9, layer A is a transparent PET film with a thickness of about 4 mil. The film has a writable bottom surface and about 2 mil thickness layer of HAA or PSA adhesive thereon. Layer B is preferably a Teslin® ® layer which is about 7 mil thick. The bottom surface is printed with instructions, preferably in black. Layer C is a PET film which is about 1 mil thick having adhesive layers on each side wherein each adhesive layer is about 2 mil thick. The adhesive is preferably HAA or PAA. Layer D is the sensor layer and is preferably about 10-14 mil thick white or opaque layer of Teslin® ® with color reference bars and other information printed on the surface. Layer E is preferably about a 4 mil thick transparent PET film with scratch-off opaque black bars printed on the top antiglare or satin surface. The bottom has about 2 mil thick layer of adhesive preferably selected from HAA and PSA. Layer F is about a 4 mil thick protective layer of black PET film with instructions printed on top and a 2-3 mil thick and 3-4 mm wide HAA or PSA tape.

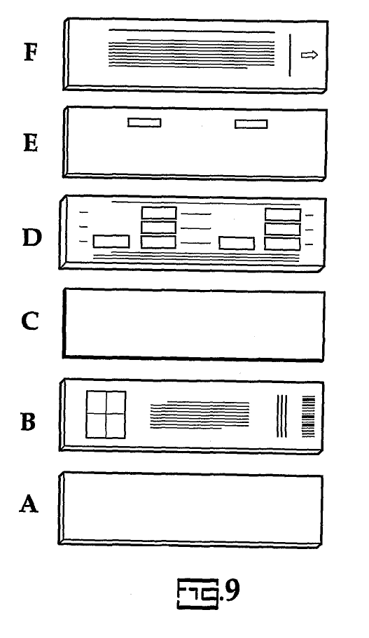

Examples of printing on the protective opaque, core and bottom layers for SIRAD cards are shown in FIGS. 10-12.

FIG. 10 illustrates a representative printed protective opaque layer including instructions.

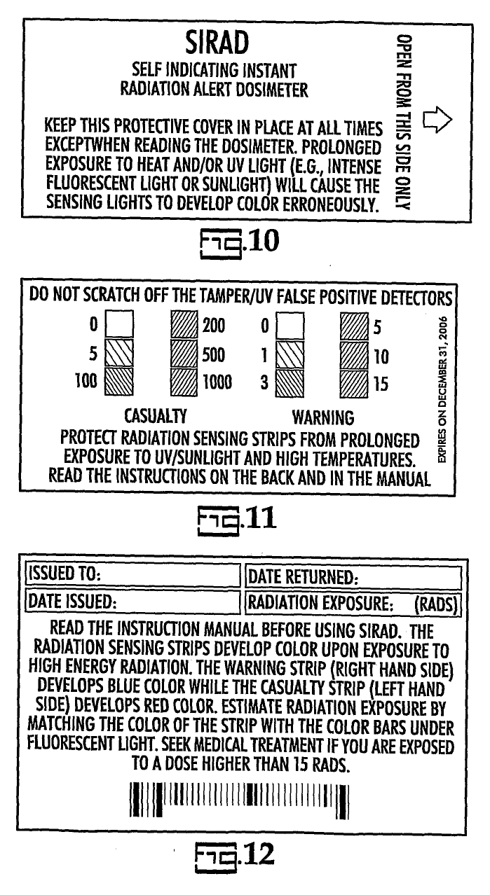

FIG. 11 illustrates a printed core layer with scales indicating the amount of radiation received and instructions for use.

FIG. 12 illustrates a printed bottom layer with instructions and locations for filling in important information.

Top, core and bottom layers could be any material such a plastic, paper and metal. The preferred material is a plastic. They could be made from natural and synthetic polymers, such as polyolefins, polyvinyls, polycarbonate, polyester, polyamide, or copolymer and block copolymers such as ABS (copolymer of acrylonitrile, butadiene and styrene) and cellulose acetate. The most preferred materials are polyesters, polycarbonates, polyolefins, polyvinyls and copolymers such as ABS. These layers could be made from the same or different plastics.

The core layer can also be a self standing heat activated adhesive.

The thickness of the layer would depend upon the nature and utility of the card. The most preferred total thickness would be between 20-40 mils (500-1,000 microns).

Transparency or opaqueness of each layer would also depend upon the application. For cards such as SIRAD, it is required that the bottom layer be opaque and the top layer be transparent. For other application, these layers could be either opaque or transparent.

The adhesive, or bonding layer, could be a pressure sensitive adhesive or heat activated adhesive. For heat activated adhesives it is particularly preferred that the adhesive have a melting point of less than 100° C. In order to make the cards tamper resistant, the prefer bonding layer is heat activated adhesive or two component bonding materials, such as polyepoxy or polyurethane or those can be cured by crosslinking. The preferred bonding layer for SIRAD cards will be low melting, especially if the sensing strip is affected by high temperature. Heat activated adhesive is preferred as it makes the cards tamper resistant and provides stronger bond than that provided by a pressure sensitive adhesive.

The process of assembling the different layers of the cards is lamination.

A further simpler way is to mold core layer with cavities; core layer with cavity and the bottom layer as one piece; or core layer with cavity and the bottom layer as one piece and further printed with required information on the bottom and color reference bars on the top.

Though the methods disclosed here can be used for making smart cards in general, they can also be used for making SIRAD cards, both with one or more sensing strips. The desired properties of the top, core and bottom layers and processes are described below:

The top transparent layer can be PET, PETG (glycolated PET) or PVC (polyvinylchloride). Preferred is PET. The top surface is preferably treated physically or chemically for antiglare and scratch resistance. It is preferred that the scratch resistance by at least equivalent to the scratch resistance of PET fihn. It is most preferable to include UV absorbance. UV absorbing PET film are commercially available. It is preferred that the top transparent layer be highly transparent and clear with no coloration such as yellowing since this may interfere with the determination of the color of the indicator. The top surface should strongly bond with two sided PSA tape or HAA tape of about ¼ inch width with the black/opaque protective film. The bond with the core material is preferably more than 10 lb/inch. The thickness is preferably 5-10 mils (125-250 microns). If black or highly opaque scratch-off bars are used it is preferable that they pass a standard cross-hatch tape test in accordance with a standard test such as ASTM D2197, D2248, D3454 or D5178. The top surface should be printable.

The middle core layers could be a plastic film, such as PVC, PET or polyolefin (such as Teslin® or Artisyn®) with die-cut cavities for sensing strips. The film will require a bonding layer such as a heat activated adhesive on each side. The layers are preferably bonded with the bottom layer to create wells or cavities for the sensing strip(s). The layers preferably do not react with any component of the sensing strip. The layers should not affect performance of the sensing strip. The layers should strongly bonded, preferably at 10 lb/inch or higher) with the top and bottom films. The layers should preferably be opaque. The layers should be printable for color reference bars and other instructions. It is preferable that the minimum thickness is that of the sensing strip.

A preferred core material is commercially available polyolefin membrane layer called Teslin® or Artisyn®. However, any other core material, such as polyester PETG and PVC, which can provide good bonding with the top and bottom layers, can be used. The bottom material can be PET, PETG, PVC Teslin® or Artisyn®. The bottom surface is preferably writable with an average ball point pen. It is highly preferred that each card have a different serial number and corresponding bar code printed on the bottom layer. The bottom material is preferably white and highly opaque. The bottom material should strongly bond with the core material with a bonding strength of preferably 10 lb/inch or higher. The preferred thickness is 5-10 mil.

### EXAMPLES

The following Examples are illustrative of carrying out the claimed invention but should not be construed as being limitations on the scope and spirit of this invention. In the examples below the encapsulant is a radiation sensing strip described in patent application No. WO 2004/077097 and WO 2004/017095 but it could be any other sensor, electronic device or any other encapsulant. Similarly, the process is exemplified with SIRAD cards but any other type of smart cards can be made.

### Example 1

Composites having the bottom opaque layer and the core layer with a cavity for the sensing strip as shown in FIG. 1 were purchased commercially. This composite was made by the conventional method of making credit card under high pressure and high temperature. The bottom layer was printed with instruction similar to that shown in FIG. 12 and a set of color reference bars similar to that shown in FIG. 11. The sensing strips were inserted and laminated with a UV absorbing transparent film having a PSA layer. This card has a PSA layer which can be peeled off.

### Example 2

Using a color laser/toner printer made by Toshiba a 12 inch×18 inch 14 mil thick Teslin®® film, available from PPG, Pittsburgh, Pa., was printed on the top with color reference bars and other information similar to that shown in FIG. 11 and the back with information similar to that shown in FIG. 12. The Teslin® film had 21 images (3 rows of 7 images each). The Teslin® film was then die-cut to create holes for the sensing strips. Die-cut Teslin® film was laminated with a 12 inch×18 inch clear 7 mil polyester film having three mil layer of heat activated adhesive using a heated roller laminator. The sensing strips were inserted in the cavities and laminated with a transparent 7 mil polyester film with 3 mil of low melting (˜85° C.) heat activated adhesive using a heated roller laminator. A 4 mil 12 inch×18 inch polyester film screen printed with white ink with information similar to that shown in FIG. 10 was laminated with a ¼ inch two sided adhesive tape. There was no bulge at the locations of the sensing strips. The laminated sheet was die-cut to make 21 cards 2⅛^{th} inch×3⅜^{th} inch with rounded corners. The different layers of the cards were very strongly bonded and they were tamper resistant.

### Example 3

SIRAD cards were made using the procedure described in Example 2 except that the bottom layer was an opaque 7 mil polyester film having a three mil layer of heat activated adhesive. The printing similar to that shown in FIG. 12 was on the bottom of the white film instead of on the Teslin®. There was no bulge at the locations of the sensing strips. The laminated sheet was die-cut to make 21 cards 2⅛^{th} inch by 3⅜^{th} inch with rounded corners. The different layers of the cards were strongly bonded and they were tamper resistant.

### Example 4

SIRAD cards were made using the procedure described in Example 3 except that the bottom layer was an opaque 8 mil polyester film with printing on the back similar to FIG. 12 and the top layer was 8 mil clear polyester film and the adhesive layers were transparent 2 mil self standing heat activated films. There was no bulge at the location of the sensing strips. The laminated sheet was die-cut to make 21 cards 2⅛^{th} inch by 3⅜^{th} inch with rounded corners. The different layers of the cards were very strongly bonded and they were tamper resistant.

### Example 5

SIRAD cards were made using the procedure described in Example 3 except that instead of Teslin® as a core layer, 10 mil polyester film etched with trichloroacetic acid was used. There was no bulge at the locations of the sensing strips. The laminated sheet was die-cut to make 21 cards 2⅛^{th} inch by 3⅜^{th} inch with rounded corners. The different layers of the cards were very strongly bonded and they were tamper resistant.

### Example 6

SIRAD cards were made using the procedure described in Example 3 except that the core layer was 6 mil polyester film with 2 mil heat activated adhesive on each side and the top layer was 10 mil clear polyester film printed with color reference bar and bottom layer was 10 mil opaque polyester film with printing on the bottom. There was no bulge at the locations of the sensing strips. The laminated sheet was die-cut to make 21 cards 2⅛^{th} inch by 3⅜^{th} inch with rounded corners. The different layers of the cards were very strongly bonded and they were tamper resistant.

What is claimed is:

1. A multi-layer smart card comprising a top layer, a core layer having at least one cavity, an encapsulant in said cavity, a bottom layer and adhesive layers between said top layer and said core layer and between said core layer and said bottom layer.

2. The multi-layer smart card of claim 1 wherein said core layer is selected from polyolefins, polyvinyl, polycarbonate, polyamide, polyester and copolymers thereof.

3. The multi-layer smart card of claim 1 wherein said adhesive layer comprises a material selected from a pressure sensitive adhesive and a heat activated adhesive.

4. The multi-layer smart card of claim 3 wherein said heat activated adhesive melts below 100° C.

5. The multi-layer smart card of claim 1 wherein at least one layer selected from said top layer, said core layer and said bottom layer is printed with information.

6. The multi-layer smart card of claim 1 wherein said encapsulant is a radiation sensitive device capable of monitoring radiation exposure.

7. The multi-layer smart card of claim 1 further comprising a protective layer on said top layer.

8. The multi-layer smart card of claim 7 wherein said protective layer is attached to said top layer by a pressure sensitive adhesive.

9. The multi-layer smart card of claim 1 further comprising at least one layer in one location selected from between said top layer and said core layer and between said bottom layer and said core layer.

10. The multi-layer smart card of claim 1 further comprising a scratch-off bar.

11. A process of making smart cards by inserting an encapsulant in a cavity of a core layer, sandwiching said core layer between a top layer and a bottom layer and laminating with adhesives.

12. A process of making of making smart cards of claim 11 wherein said cavity is formed by a method selected from die-cutting, laser cutting and casting.

13. A process of making a smart card comprising the steps of:
providing a core layer with a cavity;
providing a bottom layer;
laminating said bottom layer to said core layer;
inserting an encapsulant is said cavity; and
laminating a top layer to said core layer.

14. The process of making a smart card of claim 13 comprising providing a cavity and said bottom layer as one piece printed with instruction on a bottom and color reference bars on a top.

15. The process of making a smart card of claim 13 wherein said core layer is a self standing heat activated adhesive.

16. A process of making a smart card comprising:
providing a first layer;
providing a second layer wherein said second layer has at least one cavity;
providing a third layer;
inserting an encapsulant in said cavity;
placing said first layer, said second layer and said third layer in layered relationship; and
fusing said layered relationship to form said smart card.

17. The process for making a smart card of claim 16 further comprising an adhesive in at least one location selected from between said first layer and said second layer and between said second layer and said third layer.

18. The process for making a smart card of claim 17 wherein said adhesive is selected from heat activated adhesive and pressure sensitive adhesive.

19. The process for making a smart card of claim 16 wherein said inserting an encapsulant is said cavity is prior to said providing a third layer.

20. The process for making a smart card of claim 16 wherein said encapsulant is a radiation sensitive device.

21. The process for making a smart card of claim 16 wherein said first layer and said second layer are laminated prior to said inserting an encapsulant in said cavity.

22. The process for making a smart card of claim 16 wherein said cavity is formed by a method selected from selected from die-cutting, laser cutting and casting.
